(19) United States
(12) Patent Application Publication
(10) Pub. No.: US 2014/0361261 A1
(43) Pub. Date: Dec. 11, 2014

(54) ORGANIC LIGHT-EMITTING DISPLAY APPARATUS AND METHOD OF MANUFACTURING THE SAME

(71) Applicant: SAMSUNG DISPLAY CO., LTD., YONGIN-CITY (KR)

(72) Inventors: JIN-BAEK CHOI, YONGIN-CITY (KR); JI-YOUNG CHOUNG, YONGIN-CITY (KR); YEON-HWA LEE, YONGIN-CITY (KR); WON-JONG KIM, YONGIN-CITY (KR); HYUN-SUNG BANG, YONGIN-CITY (KR); JOON-GU LEE, YONGIN-CITY (KR)

(73) Assignee: SAMSUNG DISPLAY CO., LTD., YONGIN-CITY (KR)

(21) Appl. No.: 14/065,735

(22) Filed: Oct. 29, 2013

(30) Foreign Application Priority Data
Jun. 7, 2013 (KR) 10-2013-0065464

(51) Int. Cl. H01L 27/32; H01L 51/00; H01L 51/56

(52) U.S. Cl. CPC H01L 27/3248; H01L 51/56; H01L 51/0021
USPC 257/40; 438/23

(57) ABSTRACT

An organic light-emitting display apparatus includes a substrate, a thin film transistor (TFT) disposed on the substrate and including an active layer, a gate electrode, a source electrode, and a drain electrode The organic light-emitting display apparatus further includes a pixel electrode including a first pixel electrode layer, a second pixel electrode layer disposed on the first pixel electrode layer and a third pixel electrode layer disposed on the second pixel electrode layer. The second pixel electrode layer is a metal layer and the third pixel electrode layer is a reflective layer. The organic light-emitting display apparatus further includes an emission layer (EML) disposed on the pixel electrode, and an opposite layer disposed on the EML.

### CROSS-REFERENCE TO RELATED PATENT APPLICATION

This application claims priority to Korean Patent Application No. 10-2013-0065464, filed on Jun. 7, 2013, the disclosure of which is hereby incorporated by reference herein in its entirety.

### TECHNICAL FIELD

The present disclosure relates to an organic light-emitting display apparatus and a method of manufacturing the same, and more particularly, to an organic light-emitting display apparatus having a multi-layered pixel electrode, and a method of manufacturing the organic light-emitting display apparatus.

### DISCUSSION OF THE RELATED ART

Recently, conventional display devices have started to be replaced with portable, thin flat panel display devices. Among the flat panel display devices, organic or inorganic display devices are self-emissive display devices which may have, for example, a wide viewing angle, an excellent contrast ratio, and a high response time. Thus, the above-mentioned flat panel display devices are regarded as the next-generation display devices. Also, an organic light-emitting display apparatus including an emission layer formed of an organic material may have, for example, excellent luminosity, driving voltage, and response time characteristics, compared to inorganic light emitting display apparatuses, and may also realize multiple colors.

The organic light-emitting display apparatus has a structure in which a pixel electrode and an opposite electrode are respectively formed below and above an emission layer. Also, a top-emission type organic light-emitting display apparatus has a structure in which a pixel electrode includes, for example, a silver (Ag) material for light reflection, a transparent electrode including indium tin oxide (ITO) is formed below the pixel electrode so as to increase an adsorbing characteristic with respect to Ag, and a transparent electrode including ITO is formed above the pixel electrode so as to function as a protective layer. However, the aforementioned ITO/Ag/ITO structure may cause Ag conglomeration, and the safety of the manufacturing procedure may deteriorate due to the different etch rates of ITO and Ag.

### SUMMARY OF THE INVENTION

Exemplary embodiments of the present invention provide an organic light-emitting display apparatus having a multi-layered pixel electrode, and a method of manufacturing the organic light-emitting display apparatus, whereby the organic light-emitting display apparatus has excellent adsorbing performance and manufacturing procedure safety.

According to an exemplary embodiment of the present invention, there is provided an organic light-emitting display apparatus including a substrate, a thin film transistor (TFT) disposed on the substrate and including an active layer, a gate electrode, a source electrode, and a drain electrode. The organic light-emitting display apparatus further includes a pixel electrode including a first pixel electrode layer, a second pixel electrode layer disposed on the first pixel electrode layer and a third pixel electrode layer disposed on the second pixel electrode layer. The second pixel electrode layer is a metal layer and the third pixel electrode layer is a reflective layer. In addition, the organic light-emitting display apparatus further includes an emission layer (EML) disposed on the pixel electrode; and an opposite layer disposed on the EML.

The pixel electrode may further include a fourth pixel electrode layer that is stacked on the third pixel electrode layer and has a high work function.

The fourth pixel electrode layer may include at least one of ITO, IZO, ZnO, GZO, GIZO, GaZO, zinc oxide, and In₂O₃.

The second pixel electrode layer may include a highly heat-resistant metal material.

The second pixel electrode layer may include a metal material with a melting point equal to or less than a reference value.

The second pixel electrode layer may include at least one of Mo, W, and Ta.

The first pixel electrode layer may include at least one of Ag, Mg, Al, Pt, Pd, Au, Ni, Nd, Ir, Cr, Li, Ca, Mo, Ti, W, MoW, and Al/Cu.

The third pixel electrode layer may include at least one of an aluminum alloy, Ti, Mo, MoW, and Ag.

The first pixel electrode layer may contact a pixel defining layer (PDL) formed on the TFT, and may be connected to the source electrode or the drain electrode via an opening in the PDL.

According to an exemplary embodiment of the present invention, there is provided a method of manufacturing an organic light-emitting display apparatus, the method including forming an active layer on a substrate, and forming a thin film transistor (TFT) on the substrate. The TFT includes an active layer, a gate electrode, a source electrode, and a drain electrode. The method further includes forming a pixel electrode connected to the source electrode of the TFT. The pixel electrode includes a first pixel electrode layer, a second pixel electrode layer disposed on the first pixel electrode layer, and a third pixel electrode layer disposed on the second pixel electrode layer. The second pixel electrode layer is a metal layer. In addition, the method further includes forming an emission layer (EML) on the pixel electrode, and forming an opposite layer on the EML.

The pixel electrode may further include a fourth pixel electrode layer disposed on the third pixel electrode layer and that has a high work function.

The method of forming the pixel electrode may include stacking a first conductive layer to be connected to the source electrode, stacking a second conductive layer on the first conductive layer, stacking a third conductive layer on the second conductive layer, stacking a fourth conductive layer on the third conductive layer, and simultaneously etching the first through fourth conductive layers, thereby forming first through fourth pixel electrode layers, respectively.

The fourth pixel electrode layer may include at least one of ITO, IZO, ZnO, GZO, GIZO, and In₂O₃.

The second pixel electrode layer may be formed of a highly heat-resistant metal material having a melting point which is no greater than a reference value.

The second pixel electrode layer may include at least one of Mo, W, and Ta.

The first pixel electrode layer may include at least one of Ag, Mg, Al, Pt, Pd, Au, Ni, Nd, Ir, Cr, Li, Ca, Mo, Ti, W, MoW, and Al/Cu.

The third pixel electrode layer may include at least one of an aluminum alloy, Ti, Mo, MoW, and Ag.

The first pixel electrode layer may contact a pixel defining layer (PDL) formed on the TFT, and may be connected to the source electrode or the drain electrode via an opening in the PDL.

According to an exemplary embodiment of the present invention, there is provided an organic light-emitting display apparatus including a pixel electrode connected to a thin film transistor (TFT), an opposite electrode facing the pixel electrode, and an emission layer (EML) disposed between the pixel electrode and the opposite electrode, and including an emission material. The pixel electrode includes a first pixel electrode layer including at least one of Ag, Mg, Al, Pt, Pd, Au, Ni, Nd, Ir, Cr, Li, Ca, Mo, Ti, W, MoW, and Al/Cu, a second pixel electrode layer including at least one of Mo, W, and Ta, a third pixel electrode layer including at least one of an aluminum alloy, Ti, Mo, MoW, and Ag, and a fourth pixel electrode layer including at least one of ITO, IZO, ZnO, GZO, GIZO, and In₂O₃.

According to an exemplary embodiment of the present invention, an organic light-emitting display apparatus is provided. The organic light-emitting display apparatus includes a substrate, a buffer layer disposed on a top surface of the substrate, a gate insulating layer disposed on the buffer layer, a thin film transistor (TFT) including an active layer disposed on the buffer layer, a gate electrode disposed on the gate insulating layer, a source electrode and a drain electrode respectively contacting a source area and a drain area of the active layer, an interlayer insulating layer disposed on the gate electrode, and a passivation layer covering the TFT and the interlayer insulating layer.

The organic light-emitting display apparatus further includes an organic light-emitting diode (OLED) disposed on the passivation layer in an emission area of the organic light emitting display apparatus, and the OLED includes a pixel electrode including a first pixel electrode layer disposed on the passivation layer, a second pixel electrode layer disposed on the first pixel electrode layer, a third pixel electrode layer disposed on the second pixel electrode layer and a fourth pixel electrode layer disposed on the third pixel electrode layer, an opposite electrode facing the pixel electrode and an emission layer (EML) disposed between the fourth pixel electrode layer and the opposite electrode. The second pixel electrode layer includes a heat resistant material. The third pixel electrode layer is a reflective layer and the fourth pixel electrode layer is a transparent layer including a material having a high work function.

In addition, the organic light-emitting apparatus further includes a pixel defining layer disposed on edges of the pixel electrode thereby defining an opening which exposes a portion of the upper surface of the fourth pixel electrode layer of the pixel electrode, an encapsulation substrate disposed on the opposite electrode, and a color layer disposed between the encapsulation substrate and the opposite electrode. The EML is disposed in the opening and on the exposed portion of the upper surface of the fourth pixel electrode layer of pixel electrode and the EML is configured to emit light.

### BRIEF DESCRIPTION OF THE DRAWINGS

Exemplary embodiments of the present invention can be understood in more detail from the following detailed description taken in conjunction with the attached drawings in which:

FIG. 1 is a cross-sectional view illustrating an organic light-emitting display apparatus according to an embodiment of the present invention;

FIG. 2 is a cross-sectional view illustrating in detail a portion of the organic light-emitting display apparatus of FIG. 1;

FIG. 3 is a cross-sectional view illustrating in detail a portion of an organic light-emitting display apparatus, according to an embodiment of the present invention; and

FIGS. 4 and 5 are cross-sectional views sequentially illustrating a method of manufacturing an organic light-emitting display apparatus, according to an embodiment of the present invention.

### DETAILED DESCRIPTION OF EXEMPLARY EMBODIMENTS OF THE INVENTION

Hereinafter, exemplary embodiments of the present invention will be described in detail by explaining exemplary embodiments of the invention with reference to the attached drawings. Exemplary embodiments of the invention may, however, be embodied in many different forms and should not be construed as being limited to exemplary embodiments set forth herein. Like reference numerals in the drawings denote like or similar elements throughout the specification.

It will be understood that when a layer, a film, a region, a plate, or the like is referred to as being “on” another layer, film, region, or plate, the layer, film, region, or plate can be directly on another layer, film, region, or plate or an intervening layer, film, region, or plate may also be present.

In the drawings, the thicknesses of layers and regions may be exaggerated for clarity.

As used herein, the term “and/or” includes any and all combinations of one or more of the associated listed items. In addition, as used herein, the singular forms, “a”, “an”, and “the” are intended to include plural forms as well, unless the context clearly indicates otherwise.

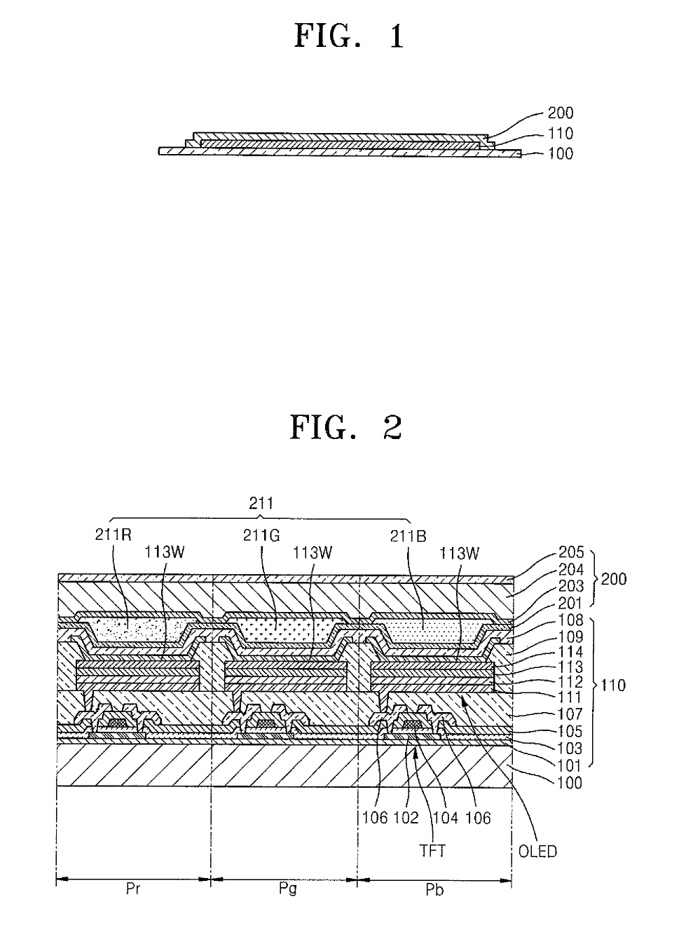

FIG. 1 is a cross-sectional view illustrating an organic light-emitting display apparatus according to an embodiment of the present invention.

Referring to FIG. 1, the organic light-emitting display apparatus includes, for example, a substrate 100, a display unit 110 formed on the substrate 100, and an encapsulation substrate 200 formed above the substrate 100 so as to cover the display unit 110.

The substrate 100 may be, for example, a crystalline silicon (LTPS) substrate, a glass substrate, quartz substrate or a plastic substrate. Alternatively, the substrate 100 may be, for example, a flexible substrate having flexibility. The flexible substrate may be formed of a plastic material, such as, for example, polyethyeleneterepthalate (PET), polyethyelenennapthalate (PEN), polycarbonate (PC), polyallylate, polyetherimide (PEI), polyethersulphone (PES), polyimide (PI), or the like, which has excellent heat-resistance and durability. However, the material of the substrate 100 is not limited thereto and may include other various flexible materials. However, as noted above, exemplary embodiments of the present invention are not limited to flexible substrates. For example, in an embodiment, the substrate 100 may be a rigid substrate formed of a glass material containing silicon oxide (SiO₂) as a main component.

If the organic light-emitting display apparatus is a bottom emission-type organic light-emitting display device in which an image is realized toward the substrate 100, the substrate 100 is formed of a transparent material. However, if the organic light-emitting display apparatus is a top emission-type organic light-emitting display device in which an image is realized away from the substrate 100, the substrate 100 may not be formed of a transparent material. In this case, the substrate 100 may be formed of, for example, a metal. When the substrate 100 is formed of metal, the substrate 100 may include, but is not limited to, at least one material selected from the group consisting of carbon, iron, chrome, manganese, nickel, titanium, molybdenum, and stainless using steel (SUS). The substrate 100 may be formed of, for example, a metal foil.

The display unit 110 may be disposed on the substrate 100. Throughout the specification, the term ‘display unit’ collectively refers to an organic light-emitting diode (OLED) and a thin film transistor (TFT) that drives the OLED, and means both a portion for displaying an image and other portion for driving the portion that displays the image.

The encapsulation substrate 200 is, for example, formed above the substrate 100 so as to cover the display unit 110. The OLED included in the display unit 110 is formed of an organic material, and thus, may readily deteriorate due to external moisture or oxygen. Thus, to protect the display unit 110, the display unit 110 should be encapsulated. The substrate 100 and the encapsulation substrate 200 may be attached to each other by, for example, a sealing member (not shown) that is disposed along their sides.

Alternatively, in an embodiment, the encapsulation substrate 200, as a thin film encapsulation substrate, has, for example, a stack structure in which a plurality of inorganic layers and a plurality of organic layers alternate with each other so as to encapsulate the display unit 110. As described above, when the display unit 110 is encapsulated by using the encapsulation substrate 200, not a sealing substrate, the organic light-emitting display apparatus may be made to be slim and flexible.

FIG. 2 is a cross-sectional view illustrating in detail a portion of the organic light-emitting display apparatus of FIG. 1. For example, FIG. 2 illustrates detailed cross-sections of the display unit 110 and the encapsulation substrate 200. When the display unit 110 is viewed in a planar direction, a plurality of pixels are, for example, matrix-arrayed. In addition, each of the pixels include a red pixel Pr that emits red light, a green pixel Pg that emits green light, and a blue pixel Pb that emits blue light. For convenience of description, FIG. 2 illustrates cross-sections of 3 pixels of 3 colors but exemplary embodiments of the present invention are not limited thereto.

Each of the pixels includes, for example, an OLED and an electronic device electrically connected to the OLED. The electronic device may include, for example, at least two TFTs, a storage capacitor, or the like. The electronic device is electrically connected to wires so that the electronic device is driven by receiving an electrical signal from a driving unit outside the display unit 110. The aforementioned array including the electronic device and the wires that are electrically connected to the OLED is referred to as the TFT array.

For convenience of description, FIG. 2 illustrates only the OLED and a driving TFT that drives the OLED, but exemplary embodiments of the present invention are not limited thereto. For example, in an embodiment, the organic light-emitting display apparatus may further include a plurality of TFTs, storage capacitors, and various wires.

The TFT shown in FIG. 2 is, for example, a top-gate type TFT that sequentially includes an active layer 102, a gate electrode 104, and source and drain electrodes 106. Although the present embodiment is related to the top-gate type TFT, it is understood that exemplary embodiments of the invention are not limited to the shape of the TFT shown in FIG. 2 but rather the TFT may have one of various types.

A buffer layer 101 may be disposed on a top surface of the substrate 100 so as to allow planarization of the substrate 100 and to prevent the diffusion of foreign substances or materials, such as, for example, moisture or impurities from the substrate 100. The buffer layer 101 may include, for example, silicon oxide, silicon nitride, and/or silicon oxynitride, and may be deposited by, for example, using silicon oxide (SiO₂) and/or silicon nitride (SiNx) via various methods including, for example, a plasma-enhanced chemical vapor deposition (PECVD) method, an atmospheric pressure CVD (APCVD) method, a low-pressure CVD (LPCVD) method, or the like. If not required, the buffer layer 101 may not be formed.

An active layer 102 is formed on predetermined areas of the buffer layer 101, and the areas correspond to the pixels, respectively. The active layer 102 may be formed by, for example, forming an inorganic semiconductor such as an oxide semiconductor or an organic semiconductor on an entire surface of the buffer layer 101 on the substrate 100 and then patterning the same. In an embodiment, the active layer 102 may be made of, for example, amorphous silicon (e.g. hydrogenated amorphous silicon). Alternatively, in an embodiment, the active layer 102 may be formed of, for example, polysilicon, micro-crystal silicon, or single crystal silicon.

For example, when the active layer 102 is formed of silicon, an amorphous silicon layer is formed on the entire surface of the buffer layer 101 and is then crystallized to thereby form a polycrystalline silicon layer. Then, the polycrystalline silicon layer is patterned and side areas of the polycrystalline silicon layer are doped with impurities. In this manner, the active layer 102 is formed to include a source area, a drain area, and a channel area between the source area and the drain area.

Afterward, a gate insulating layer 103 is formed of, for example, SiO2, SiNx, silicon oxynitride (SiOxNy), aluminum oxide (AlOx), yttrium oxide (Y₂O₃), hafnium oxide (HfOx), zirconium oxide (ZrOx), aluminum nitride (AlN), aluminum oxynitride (AlNO), titanium oxide (TiOx), barium titanate (BaTiO3), lead titanate (PbTiO₃), or a combination thereof, on the active layer 102. A gate electrode 104 is formed on a predetermined area on the gate insulating layer 103. The gate electrode 104 is connected to a gate line (not shown) that applies ON/OFF signals of the TFT.

The gate electrode 104 may be formed of, for example, a conductive metal, and may be a single layer or a multi-layer formed from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), zinc (Zn), cobalt (Co), manganese (Mn), iridium (Ir), rhodium (Rh), osmium (Os), tantalum (Ta), or a compound of any of these.

An interlayer insulating layer 105 is formed, for example, on the gate electrode 104, and the source and drain electrodes 106 are formed to respectively contact the source area and the drain area of the active layer 102 via contact holes. Afterward, the TFT is covered by, for example, a passivation layer 107. Thus, protection of the TFT is ensured.

The source and drain electrodes 106 may be formed of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), zinc (Zn), cobalt (Co), manganese (Mn), iridium (Ir), rhodium (Rh), osmium (Os), tantalum (Ta), or a compound of any of these.

The passivation layer 107 may be formed by using, for example, an inorganic insulating layer and/or an organic insulating layer. The inorganic insulating layer may include, for example, silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zirconium oxide (ZrO₂), boron strontium titanate (BST), lead zirconate titanate (PZT), or a combination thereof. The organic insulating layer may include, for example, polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinyl alcohol-based polymer, or a combination thereof. Also, the passivation layer 107 may be formed as, for example, a multi-stack including the inorganic insulating layer and the organic insulating layer.

The OLED is formed in an emission area on the passivation layer 107.

The OLED includes a pixel electrode including, for example, a first pixel electrode layer 111, a second pixel electrode layer 112, a third pixel electrode layer 113 and a fourth pixel electrode layer 114 that are formed on the passivation layer 107, an opposite electrode 108 facing the pixel electrode, and an intermediate layer interposed between the pixel electrode and the opposite electrode 108.

The organic light-emitting display apparatus may be divided into, for example, a bottom-emission type organic light-emitting display apparatus, a top-emission type organic light-emitting display apparatus, and a dual-emission type organic light-emitting display apparatus. In the bottom-emission type organic light-emitting display apparatus, the pixel electrode is formed as, for example, a light-transmitting electrode, and the opposite electrode 108 is formed as, for example, a reflective electrode. In the top-emission type organic light-emitting display apparatus, the pixel electrode is formed as, for example, a reflective electrode, and the opposite electrode 108 is formed as, for example, a transflective electrode. In the present embodiment, it is assumed that the organic light-emitting display apparatus is the top-emission type organic light-emitting display apparatus in which the OLED emits light toward the encapsulation substrate 200.

The pixel electrode includes, for example, the first pixel electrode layer 111, the second pixel electrode layer 112, the third pixel electrode layer 113, and the fourth pixel electrode layer 114. The pixel electrode may be patterned into, for example, an island form separate for each pixel. Also, the pixel electrode may be connected to, for example, an external terminal (not shown), thereby functioning as an anode electrode.

The first pixel electrode layer 111 may be formed of, for example, silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), molybdenum (Mo), titanium (Ti), tungsten (W), molybdenum-tungsten (MoW), aluminum (Al)/copper (Cu), or a compound of any of these. For example, in an embodiment, the first pixel electrode layer 111 may be formed of Al, and may increase layer stability by increasing an adsorbing characteristic with respect to the passivation layer 107.

The second pixel electrode layer 112 may be formed of, for example, a heat-resistant metal material such as Mo, W, Ta, or a compound of any of these. The second pixel electrode layer 112 is formed of highly heat-resistant metal, thereby functioning as a heat diffusion stopping layer that prevents the first pixel electrode layer 111 and the third pixel electrode layer 113 from alloying with each other. The second pixel electrode layer 112 may be formed of, for example, a metal material with a melting point no greater than a reference value.

The third pixel electrode layer 113 includes, for example, at least one of an aluminum alloy, Ti, Mo, MoW, and Ag. For example, here in the present embodiment, the aluminum alloy includes AI and at least one of silicon (Si), nickel (Ni), lanthanum (La), germanium (Ge) and cobalt (Co). The third pixel electrode layer 113 may function as a metal mirror that transmits or reflects part of light. That is, the third pixel electrode layer 113 may be used as a transflective mirror of the organic light-emitting display apparatus that employs an optical resonance structure. For example, in an embodiment, the third pixel electrode layer 113 may be a reflective layer formed of Ag. When the organic light-emitting display apparatus is a top-emission type organic light-emitting display apparatus, the third pixel electrode layer 113 may reflect light that is emitted from an emission layer (EML) 113W.

The fourth pixel electrode layer 114 may be, for example, a transparent layer formed of indium tin oxide (ITO), indium zinc oxide (IZO), zinc oxide (ZnO), gallium zinc oxide (GZO), gallium indium zinc oxide (GIZO), or indium oxide (In₂O₃) having a high work function. The fourth pixel electrode layer 114 may increase a hole injection characteristic of the EML 113W by assuring stability from an external solution and by controlling a work function.

As described above, the pixel electrode may have a structure, for example, in which the first through fourth electrode layers 111 through 114 are stacked. For example, in an embodiment, the first pixel electrode layer 111, the second pixel electrode layer 112, the third pixel electrode layer 113, and the fourth pixel electrode layer 114 may be formed of Al, metal (Mo, W, or Ta), Ag, and ITO, respectively.

A pixel defining layer (PDL) 109 is formed, for example, on the pixel electrode. The PDL 109 includes, for example, an opening that covers side portions of the pixel electrode and exposes a center portion of the pixel electrode. The EML 113W that emits light is deposited in an area defined by the opening so that the emission area is defined. When a plurality of the emission areas are formed in the PDL 109 by using the openings, a portion that projects further than the emission area is naturally formed between the emission areas, and in this regard, as the EML 113W is not formed in the portion, the portion corresponds to a non-emission area.

The opposite electrode 108 may be formed as, for example, a transmissive electrode. The opposite electrode 108 may be, for example, a transflective layer that is thinly formed by using Li, Ca, LiF/Ca, LiF/Al, Al, Mg, Ag or the like having a small work function. By forming a transparent conductive layer including ITO, IZO, ZnO, or In₂O₃ on the metal transflective layer, a high resistance difficulty due to a thickness of the thin metal transflective layer may be complemented. The opposite electrode 108 may be formed as, for example, a common electrode on an entire surface of the substrate 100. Also, the opposite electrode 108 may be connected to, for example, an external terminal (not shown), thereby functioning as a cathode electrode.

However, in an embodiment, polarities of the pixel electrode and the opposite electrode 108 may be switched.

The intermediate layer includes, for example, the EML 113W that emits light. The EML 113W may be formed by using as a small molecule organic material or a polymer organic material. For example, when the EML 113W is a small molecule organic layer formed of a small molecule organic material, a hole transport layer (HTL) and a hole injection layer (HIL) may be stacked below the EML 113W toward the pixel electrode, and an electron transport layer (ETL) and an electron injection layer (EIL) may be stacked on the EML toward the opposite electrode 108. In addition to these layers, various layers including an HIL, an HTL, an ETL, an EIL or the like may be stacked on or below the EML 113W according to necessity.

For example, when the EML 113W is a polymer organic layer formed of a polymer organic material, only a polymer HTL may be stacked on the EML 113W toward the pixel electrode. The polymer HTL is formed of, for example, poly(3,4-ethylenedioxythiophene) (PEDOT) or polyaniline (PANI) on the pixel electrode by using, for example, an inkjet printing method or a spin coating method.

As illustrated in FIG. 2, the OLED according to the present embodiment emits white light when the pixel electrode and the opposite electrode 108 are electrically driven. Here, the white light emitted from the EML 113W may include, but is not limited to, having an excellent color rendering index (CRI) (>75) and may be close to coordinates (0.33, 0.33) in a CIE diagram.

For example, to allow the EML 113W to emit white light, a wave conversion method such as down conversion may be performed, in which a phosphor is excited to a blue color or a purple color and then a wave spectrum having a wide and rich area is formed by mixing various colors that are emitted from the phosphor, and a color mixing method may also be performed, in which white light is formed by mixing two base colors (blue and orange colors) or three base colors (red, green, and blue colors). Exemplary embodiments of the present invention are not limited thereto, and thus, other various materials and methods may be used to realize white color.

As described above, the encapsulation substrate 200 is formed above the substrate 100 so as to cover the display unit 110. For example, when the encapsulation substrate 200 is a thin film encapsulation substrate, the encapsulation substrate 200 is formed of a plurality of stacked insulating layers. For example, in an embodiment, the plurality of stacked insulating layers of the encapsulation substrate 200 may include an organic layer 204 and inorganic layers 201, 203, and 205 that are alternately stacked.

The inorganic layers 201, 203, and 205 may be formed of, for example, a metal oxide, a metal nitride, a metal carbide, or a compound of any of these. For example, the inorganic layers 201, 203, and 205 may be formed of an aluminum oxide, a silicon oxide, or a silicon nitride. The inorganic layers 201, 203, and 205 may prevent external moisture and oxygen from penetrating into the OLED. The organic layer 204 may be, for example, a polymer organic compound and may include, for example, one of an epoxy, an acrylate, or a urethaneacrylate. The organic layer 204 may decrease an inner stress of the inorganic layers 201, 203, and 205, or may compensate for a defect of the inorganic layers 201, 203, and 205 and may planarize the inorganic layers 201, 203, and 205.

In the present embodiment, a color layer 211 is, for example, interposed between the encapsulation substrate 200 and the opposite electrode 108. The color layer 211 functions as a color adjusting member such as a color filter and may simultaneously complement a function of the encapsulation substrate 200.

For example, the color layer 211 may include a coloring material and an organic material in which coloring materials are dispersed, and in this regard, the coloring material may be a general pigment or dyes, and the organic material may be a general dispersant. The color layer 211 selectively transmits light of a specific wavelength such as red light, green light, or blue light from among white light emitted from the OLED, and then absorbs light of the other wavelengths, so that the color layer 211 allows each pixel to emit one of red light, green light, and blue light. For example, as described above, colors layers 211R, 211G, and 211B having a red color, a green color, and a blue color, respectively are disposed to correspond to emission areas, respectively. The emission areas emit a red color, a green color, and a blue color, respectively.

As a top surface of the color layer 211 is almost planar, a thickness of the encapsulation substrate 200 may become slimmer. In the encapsulation substrate 200 in which the organic layer 204 and the inorganic layers 201, 203, and 205 are alternately stacked, the organic layer 204 may have, for example, a thickness greater than a thickness of the inorganic layers 201, 203, and 205, so that the organic layer 204 may complement the defect of the inorganic layers 201, 203, and 205 and may planarize the inorganic layers 201, 203, and 205. According to the present embodiment, when the color layer 211 is formed to compensate for irregularity of the display unit 110 and to planarize the top surface of the substrate 100, it is possible to decrease the number of stacking the organic layer 204 and a thickness of the organic layer 204 included in the encapsulation substrate 200.

Although not illustrated, the color layer 211 may, for example, completely fill the opening of the PDL 109 so that a top surface of the color layer 211 may be almost even with a top surface of the inorganic layer 201 on the PDL 109, or the top surface of the color layer 211 may be lower than the top surface of the inorganic layer 201 on the PDL 109. By doing so, planarization by the encapsulation substrate 200 may be readily achieved.

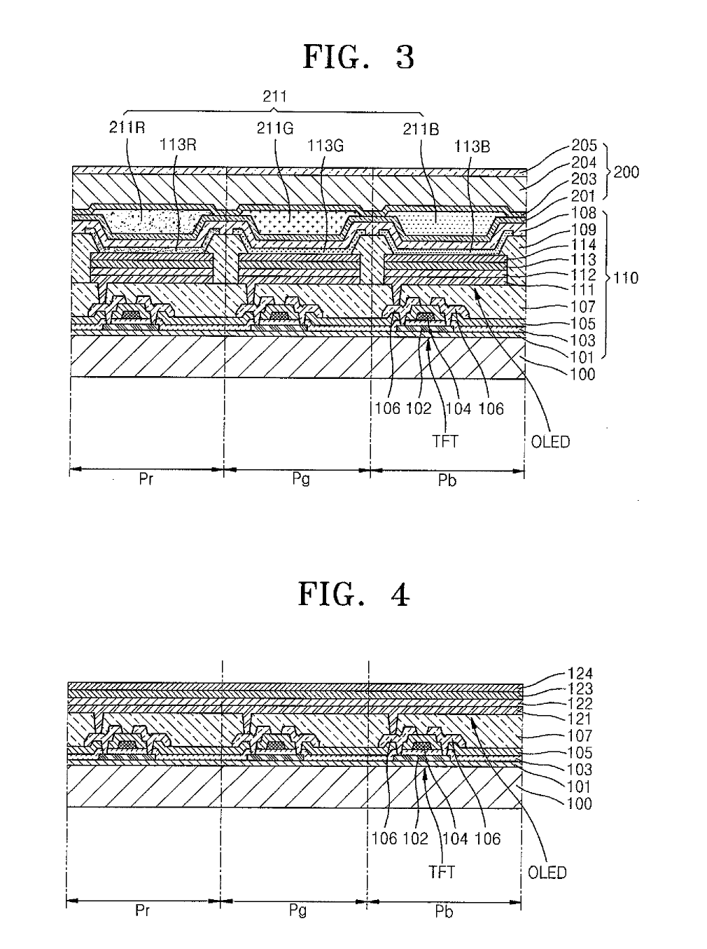

FIG. 3 is a cross-sectional view illustrating in detail a portion of an organic light-emitting display apparatus, according to an embodiment of the present invention.

Referring to FIG. 3, the organic light-emitting display apparatus of the present embodiment is different from the organic light-emitting display apparatus of the previous embodiment in that EMLs 113R, 113G, and 113B in the organic light-emitting display apparatus of the present embodiment do not emit white light but instead emit a red color, a green color, and a blue color, respectively. Except for this difference in FIGS. 2 and 3, the same or corresponding components are referred to by the same reference numeral, and redundant explanations are omitted.

As illustrated in FIG. 3, each of pixels in the OLED emits a red color, a green color, or a blue color by, for example, electrically driving the pixel electrode including the first through fourth pixel electrode layers 111 through 114, and the opposite electrode 108. The color layer 211 has a color the same as a color emitted from the OLED. For example, a red color layer 211R is disposed to correspond to a red emission area, a green color layer 211G is disposed to correspond to a green emission area, and a blue color layer 211B is disposed to correspond to a blue emission area. In the present embodiment of FIG. 3, the color layer 211 mainly complements the function of the encapsulation substrate 200, compared to a function as the color adjusting member.

In the present embodiment of FIG. 3, the pixel electrode may also have a stack structure including, for example, four layers but exemplary embodiments of the present invention are not limited thereto. For example, the first pixel electrode layer 111, the second pixel electrode layer 112, the third pixel electrode layer 113, and the fourth pixel electrode layer 114 may be formed of Al, metal (Mo, W, or Ta), Ag, and ITO, respectively.

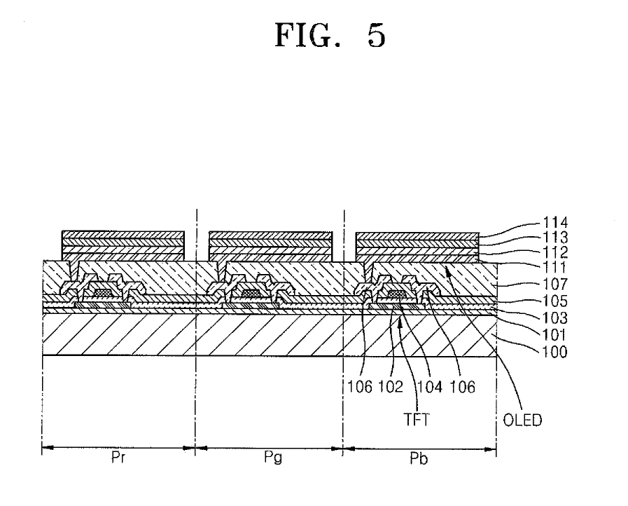

FIGS. 4 and 5 are cross-sectional views sequentially illustrating a method of manufacturing the organic light-emitting display apparatus, according to an embodiment of the present invention. FIG. 4 illustrates that conductive layers that form a pixel electrode are sequentially stacked on the TFT.

A process of forming the TFT array on the substrate 100 has been already described above and is a general process, and thus, redundant explanations are omitted. FIGS. 4 and 5 illustrate a method of manufacturing the organic light-emitting display apparatus shown in FIG. 2. Also, in an embodiment, the organic light-emitting display apparatus shown in FIG. 3 may be manufactured by using the same method.

For example, referring to FIG. 4, a first conductive layer 121, a second conductive layer 122, a third conductive layer 123, and a fourth conductive layer 124 are formed on the substrate 100 whereon the TFT is formed.

The first conductive layer 121 may be connected to one of the source and drain electrodes 106 via the opening. The first conductive layer 121 may be formed of, for example, Ag, Mg, Al, Pt, Pd, Au, Ni, Nd, Ir, Cr, or a compound of any of these. The first conductive layer 121 may be formed of, for example, Al, and may be stacked on the passivation layer 107 so as to increase an adsorbing characteristic of the pixel electrode.

The second conductive layer 122 may be formed of, for example, a heat-resistant metal material such as Mo, W, Ta, or a compound of any of these. The second conductive layer 122 is formed of metal that is highly heat-resistant, thereby functioning as a heat diffusion stopping layer that prevents the first conductive layer 121 and the third conductive layer 123 from alloying with each other.

The third conductive layer 123 may be formed of, for example, Ag, Mg, Al, Pt, Pd, Au, Ni, Nd, Ir, Cr, or a compound of any of these. For example, the third conductive layer 123 may be a reflective layer formed of Ag. When the organic light-emitting display apparatus is a top-emission type organic light-emitting display apparatus, the third conductive layer 123 may reflect light that is emitted from an EML (refer to 113W of FIG. 2 or 113R, 113G, 113B of FIG. 3).

The fourth conductive layer 124 may be, for example, a transparent layer formed of ITO, IZO, ZnO, GZO, GIZO, or In₂O₃ having a high work function. The fourth conductive layer 124 may increase a hole injection characteristic of the EML 113W by ensuring the stability of the EML 113W to an external solution and by controlling a work function of the EML 113W.

FIG. 5 illustrates a result after the first through fourth conductive layers 121 through 124 are etched.

Referring to FIG. 5, the first through fourth conductive layers 121 through 124 are, for example, etched at one time by using a predetermined mask. According to the etch result, the first conductive layer 121, the second conductive layer 122, the third conductive layer 123, and the fourth conductive layer 124 are patterned to form the first pixel electrode layer 111, the second pixel electrode layer 112, the third pixel electrode layer 113, and the fourth pixel electrode layer 114 of each pixel, respectively.

Afterward, referring to FIG. 2, the PDL 109 that is an insulating layer having a predetermined thickness for covering the pixel electrode is formed on the pixel electrode. The PDL 109 may be formed of, for example, an organic insulating material selected from the group consisting of a polyimide, a polyimide, an aryl resin, a benzocyclo butane, and a phenol resin, by using, for example, a spin coating method. For example, when the opening is formed in the PDL 109 so as to expose a center portion of the pixel electrode, and then the EML 113W that emits light is deposited in an area defined by the opening, an emission area is defined.

Afterward, the opposite electrode 108 is formed, for example, by thinly depositing a transflective layer that is formed of metal such as Li, Ca, LiF/Ca, LiF/Al, Al, Mg, Ag or the like, and then the encapsulation substrate 200 is formed on the opposite electrode 108. First, the inorganic layer 201 is formed to have a predetermined thickness. Here, a separate layer such as a protective layer (not shown) may be further formed between the encapsulation substrate 200 and the OLED, but a filling material due to a sealing member to form a sealing substrate is not required.

Afterward, referring to FIG. 3, the color layer 211 may be formed by, for example, using an inject method or a flash evaporation method. For example, as illustrated in FIG. 2, the color layer 211 may be formed while filling a groove that corresponds to the opening of the PDL 109. However, the forming of the color layer 211 is not limited thereto and thus may be, for example, flat.

Afterward, another inorganic layer 203 is formed on, for example, a flat top surface of the color layer 211 and the inorganic layer 201 that corresponds to a top surface of the the opposite electrode 108. If desired, the organic layer 204 and the inorganic layer 205 may be further stacked on the other inorganic layer 203. Also, when the encapsulation substrate 200 is not a thin film encapsulation substrate, the encapsulation substrate 200 may be formed as, for example, a single substrate.

Referring to FIGS. 2 and 3, the OLED is formed on the passivation layer 107, but exemplary embodiments of the present invention are not limited thereto. Thus, the OLED may be formed on the gate insulating layer 103 or the interlayer insulating layer 105 via, for example, a mask decreasing process.

Exemplary embodiments of the present invention may be applied to, for example, a dual-emission type organic light-emitting display apparatus in which all of the opposite electrode 108 and the pixel electrode including the first through fourth pixel electrode layers 111 through 114 are formed as light-transmitting electrodes.

According to the organic light-emitting display apparatus and method of manufacturing the same of exemplary embodiments of the present invention, the pixel electrode in the organic light-emitting display apparatus may be multi-layered so that an adsorbing characteristic and manufacturing procedure safety may be increased.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. An organic light-emitting display apparatus comprising:
a substrate;
a thin film transistor (TFT) disposed on the substrate and comprising an active layer, a gate electrode, a source electrode, and a drain electrode;
a pixel electrode comprising a first pixel electrode layer, a second pixel electrode layer disposed on the first pixel electrode layer, and a third pixel electrode layer disposed on the second pixel electrode layer, wherein the second pixel electrode layer is a metal layer and the third pixel electrode layer is a reflective layer;
an emission layer (EML) disposed on the pixel electrode; and
an opposite layer disposed on the EML.

2. The organic light-emitting display apparatus of claim 1, wherein the pixel electrode further comprises a fourth pixel electrode layer that is stacked on the third pixel electrode layer and has a high work function.

3. The organic light-emitting display apparatus of claim 2, wherein the fourth pixel electrode layer comprises at least one selected from the group consisting of indium tin oxide (ITO), indium zinc oxide (IZO), zinc oxide (ZnO), gallium zinc oxide (GZO), gallium indium zinc oxide (GIZO), and indium oxide (In₂O₃).

4. The organic light-emitting display apparatus of claim 1, wherein the second pixel electrode layer includes a highly heat-resistant metal material.

5. The organic light-emitting display apparatus of claim 1, wherein the second pixel electrode layer includes a metal material with a melting point which is no greater than a reference value.

6. The organic light-emitting display apparatus of claim 1, wherein the second pixel electrode layer comprises at least one selected from the group consisting of molybdenum (Mo), tungstens (W), and tantalum (Ta).

7. The organic light-emitting display apparatus of claim 1, wherein the first pixel electrode layer comprises at least one selected from the group consisting of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), molybdenum-tungsten (MoW), and aluminum (Al)/copper (Cu).

8. The organic light-emitting display apparatus of claim 1, wherein the third pixel electrode layer comprises at least one selected from the group consisting of an aluminum alloy, titanium (Ti), molybdenum (Mo), molybdenum-tungsten (MoW), and silver (Ag).

9. The organic light-emitting display apparatus of claim 1, further comprising a pixel defining layer (PDL) disposed on the TFT, wherein the first pixel electrode layer contacts the PDL, and wherein the first pixel electrode layer is connected to the source electrode or the drain electrode via an opening in the PDL.

10. A method of manufacturing an organic light-emitting display apparatus, the method comprising:
forming an active layer on a substrate;
forming a thin film transistor (TFT) on the substrate, wherein the TFT comprises an active layer, a gate electrode, a source electrode, and a drain electrode;
forming a pixel electrode connected to the source electrode of the TFT, and wherein the pixel electrode comprises a first pixel electrode layer, a second pixel electrode layer disposed on the first pixel electrode layer, and a third pixel electrode layer disposed on the second pixel electrode layer, wherein the second pixel electrode layer is a metal layer;
forming an emission layer (EML) on the pixel electrode; and
forming an opposite layer on the EML.

11. The method of claim 10, wherein the pixel electrode further comprises a fourth pixel electrode layer disposed on the third pixel electrode layer and wherein the fourth pixel electrode layer has a high work function.

12. The method of claim 11, wherein the forming of the pixel electrode comprises:
stacking a first conductive layer to be connected to the source electrode;
stacking a second conductive layer on the first conductive layer;
stacking a third conductive layer on the second conductive layer;
stacking a fourth conductive layer on the third conductive layer; and
simultaneously etching the first through fourth conductive layers, thereby forming the first through fourth pixel electrode layers, respectively.

13. The method of claim 11, wherein the fourth pixel electrode layer comprises at least one selected from the group consisting of indium tin oxide (ITO), indium zinc oxide (IZO), zinc oxide (ZnO), gallium zinc oxide (GZO), gallium indium zinc oxide (GIZO), and indium oxide (In₂O₃).

14. The method of claim 10, wherein the second pixel electrode layer is formed of a highly heat-resistant metal material having a melting point which is no greater than a reference value.

15. The method of claim 10, wherein the second pixel electrode layer comprises at least one selected from the group consisting of molybdenum (Mo), tungsten (W), and tantalum (Ta).

16. The method of claim 10, wherein the first pixel electrode layer comprises at least one selected from the group consisting of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), molybdenum tungsten (MoW), and aluminum (Al)/copper (Cu).

17. The method of claim 10, wherein the third pixel electrode layer comprises at least one selected from the group consisting of an aluminum alloy, titanium (Ti), molybdenum (Mo), molybdenum tungsten (MoW), and silver (Ag).

18. The method of claim 10, further comprising forming a pixel defining layer (PDL) on the TFT, wherein the first pixel electrode layer contacts the PDL, and wherein the first pixel electrode layer is connected to the source electrode or is the drain electrode via an opening in the PDL.

19. An organic light-emitting display apparatus comprising:
a pixel electrode connected to a thin film transistor (TFT);
an opposite electrode facing the pixel electrode; and
an emission layer (EML) disposed between the pixel electrode and the opposite electrode, and comprising an emission material,
wherein the pixel electrode comprises:
a first pixel electrode layer comprising at least one selected from the group consisting of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), molybdenum (MoW), and aluminum (AD/copper (Cu),
a second pixel electrode layer comprising at least one selected from the group consisting of Mo, W, and tantalum (Ta),
a third pixel electrode layer comprising at least one selected from the group consisting of an aluminum alloy, Ti, Mo, MoW, and Ag, and
a fourth pixel electrode layer comprising at least one selected from the group consisting of indium tin oxide (ITO), indium zinc oxide (IZO), zinc oxide (ZnO), gallium zinc oxide (GZO), gallium indium zinc oxide (GIZO), and indium oxide (In₂O₃).

20. An organic light-emitting display apparatus comprising:
a substrate;
a buffer layer disposed on a top surface of the substrate;
a gate insulating layer disposed on the buffer layer;
a thin film transistor (TFT) comprising an active layer disposed on the buffer layer, a gate electrode disposed on the gate insulating layer, a source electrode and a drain electrode respectively contacting a source area and a drain area of the active layer;
an interlayer insulating layer disposed on the gate electrode;
a passivation layer covering the TFT and the interlayer insulating layer;
an organic light-emitting diode (OLED) disposed on the passivation layer in an emission area of the organic light emitting display apparatus, wherein the OLED comprises a pixel electrode including a first pixel electrode layer disposed on the passivation layer, a second pixel electrode layer disposed on the first pixel electrode layer, a third pixel electrode layer disposed on the second pixel electrode layer and a fourth pixel electrode layer disposed on the third pixel electrode layer, an opposite electrode facing the pixel electrode and an emission layer (EML) disposed between the fourth pixel electrode layer and the opposite electrode, wherein the second pixel electrode layer comprises a heat resistant material, wherein the third pixel electrode layer is a reflective layer and wherein the fourth pixel electrode layer is a transparent layer including a material having a high work function;
a pixel defining layer disposed on edges of the pixel electrode thereby defining an opening which exposes a portion of the upper surface of the fourth pixel electrode layer of the pixel electrode, wherein the EML is disposed in the opening and on the exposed portion of the upper surface of the fourth pixel electrode layer of pixel electrode and wherein the EML is configured to emit light;
an encapsulation substrate disposed on the opposite electrode; and
a color layer disposed between the encapsulation substrate and the opposite electrode.
